(19) United States
(12) Patent Application Publication
(10) Pub. No.: US 2026/0223374 A1
(43) Pub. Date: Jul. 30, 2026

(54) MEMORY DEVICE COMPRISING ELECTRO-CHEMICAL LAYER, METHOD FOR MANUFACTURING MEMORY DEVICE AND METHOD FOR DRIVING MEMORY DEVICE

(71) Applicant: Samsung Electronics Co., Ltd., Suwon-si (KR)

(72) Inventors: Garam PARK, Suwon-si (KR); Minhyun LEE, Suwon-si (KR); Yumin KIM, Suwon-si (KR); Hyunjae SONG, Suwon-si (KR); Jeeeun YANG, Suwon-si (KR); Seung Dam HYUN, Suwon-si (KR)

(73) Assignee: Samsung Electronics Co., Ltd., Suwon-si (KR)

(21) Appl. No.: 19/629,455

(22) Filed: Mar. 26, 2026

Related U.S. Application Data
(63) Continuation-in-part of application No. 19/097,942, filed on Apr. 2, 2025.

(30) Foreign Application Priority Data
Oct. 24, 2024 (KR) 10-2024-0146957
Oct. 28, 2025 (KR) 10-2025-0158078

(51) Int. Cl. H10B 63/00; G11C 13/00

(52) U.S. Cl. CPC H10B 63/845; G11C 13/0069; G11C 13/0097; H10B 63/34; G11C 2213/71; G11C 2213/79

(57) ABSTRACT

A memory device may include a substrate, a channel layer on a surface of the substrate and including an oxygen ion, a gate electrode on the channel layer, an electro-chemical layer between the channel layer and the gate electrode, and a gate oxide layer between the gate electrode and the electro-chemical layer, wherein the electro-chemical layer has a concentration of oxygen ions less than 90% and is capable of transferring the oxygen ions to the channel layer or receiving the oxygen ions from the channel layer, depending on a voltage applied to the gate electrode.

### CROSS-REFERENCE TO RELATED APPLICATION

This application is a continuation-in-part application of U.S. application Ser. No. 19/097,942, filed with the United States Patent and Trademark Office on Apr. 2, 2025, which claims priority to Korean Patent Application No. 10-2024-0146957 filed on Oct. 24, 2024; and which claims priority to Korean Patent Application No. 10-2025-0158078 filed on Oct. 28, 2025 and all the benefits accruing therefrom under 35 U.S.C. § 119, the contents of which are incorporated by reference in their entirety.

### BACKGROUND

Some example embodiments of the present disclosure relate to memory devices including an electro-chemical layer, methods of manufacturing the memory devices and/or methods for driving the memory devices.

Manufacturing technology for NAND flash memory devices is developing toward improving the integration density, operating speed, and/or yield of memory devices. In order to increase the integration of memory devices, vertical NAND (VNAND) flash memory devices have been suggested.

NAND flash memory devices, including vertical NAND flash memory devices, implement memory functions through the charge trap flash (CTF) method, which applies a voltage to a gate electrode to move electrons present in a channel layer to a trap layer through the tunneling effect. However, the CTF method may apply a relatively high voltage to the gate electrode, which may cause interference problems between unit cells, and thus may have limitations in reducing the thickness of the gate electrode and/or the trap layer.

Meanwhile, an electrochemical random-access memory (ECRAM) device is known that implements a memory function by applying a voltage to the gate electrode and moving ions present in the channel layer to change the electrical conductivity and/or the threshold voltage of the channel layer.

### SUMMARY

Some example embodiments of the present disclosure provide memory devices, methods of manufacturing the memory devices, and/or methods for driving the memory devices, by which a memory function is implemented even when a relatively small voltage is applied to the gate electrode and/or integration density is improved, by borrowing the operating principle of an electrochemical random-access memory device to improve the charge trap flash (CTF) method that causes technical problems due to interference problems between unit cells.

In addition, some example embodiments of the present disclosure provide memory devices with an improved memory window (M.W.) by increasing the movement of oxygen ions or oxygen vacancies in the operating principle of an electro-chemical random-access memory device, methods of manufacturing the memory devices, and/or methods of driving the memory device.

The technical tasks to be achieved by the present example embodiments are not limited to the technical tasks described above, and other technical tasks may be inferred from the following example embodiments by those skilled in the art.

According to an example embodiment of the present disclosure, a memory device may include a substrate, a channel layer on a surface of the substrate, the channel layer including an oxygen ion, a gate electrode on the channel layer, an electro-chemical layer between the channel layer and the gate electrode, and a gate oxide layer between the gate electrode and the electro-chemical layer, wherein the electro-chemical layer has a concentration of oxygen ions less than 90% and is capable of transferring the oxygen ions to the channel layer or receiving the oxygen ions from the channel layer, depending on a voltage applied to the gate electrode.

According to an example embodiment of the present disclosure, there may be provided a method of driving a memory device, the memory device including a substrate, a channel layer on a surface of the substrate and including an oxygen ion, a gate electrode between the substrate and the channel layer, an electro-chemical layer between the channel layer and the gate electrode and including oxygen ions, and a gate oxide layer between the gate electrode and the electro-chemical layer, the method including performing a write operation or an erase operation when a voltage is applied to the gate electrode by changing first values of an electrical conductivity and a threshold voltage Vₜₕ of the channel layer differently from second values before the voltage is applied to the gate electrode, and the concentration of the oxygen ions included in the electro-chemical layer is less than 90%.

According to an example embodiment of the present disclosure, a method of manufacturing a memory device may include forming an oxide layer, an electro-chemical layer, and a channel layer on a substrate, wherein the electro-chemical layer is deposited in an environment below 200° C. based on a metal precursor, and the thermal decomposition temperature of the metal precursor is below 200° C.

Details of other example embodiments are included in the Detailed Description and drawings.

### BRIEF DESCRIPTION OF THE DRAWINGS

The drawings shown in the present disclosure are according to some example embodiments, and ratios of the width, height or thickness of each component are for describing the example embodiments of the present disclosure in detail, and the ratio may be different from the actual ones. In addition, each component illustrated in the drawings may be exaggerated to describe the present disclosure in detail. In addition, in a coordinate system shown in the drawing, each axis may be perpendicular to the others, a direction pointed by an arrow may be a + direction, and a direction opposite to the direction pointed by the arrow (a direction rotated by 180 degrees) may be a − direction, in which:

FIG. 1 schematically illustrates at least a portion of a memory device according to an example embodiment of the present disclosure;

FIG. 2 illustrates a cross-section taken along line AA′ of FIG. 1;

FIG. 3 illustrates a cross-section taken along line BB′ of FIG. 1;

FIG. 4 is an enlarged view of part P in FIG. 1;

FIG. 5 schematically illustrates at least a portion of a memory device according to an example embodiment of the present disclosure;

FIG. 6 illustrates a cross-section taken along CC′ of FIG. 5;

FIG. 7 is an enlarged view of part Q in FIG. 5;

FIG. 8 schematically illustrates at least a portion of the memory device according to an example embodiment of the present disclosure;

FIG. 9 illustrates a cross-section taken along DD′ in FIG. 8;

FIG. 10 is an enlarged view of part R in FIG. 8;

FIG. 11 schematically illustrates at least a portion of a memory device according to an example embodiment of the present disclosure;

FIGS. 12 to 16 are views for describing a method of manufacturing a memory device according to an example embodiment of the present disclosure;

FIGS. 17 to 20 schematically illustrate at least a portion of a memory device to describe a method of driving the memory device according to an example embodiment of the present disclosure;

FIG. 21 is a set of graphs showing characteristics of a drain-source current (Ips) with respect to a gate-source voltage (V_{GS}) of a memory device according to examples and a comparative example of the present disclosure;

FIG. 22 is a graph showing results of analyzing electro-chemical layers of memory devices according to examples and comparative examples of the present disclosure, using secondary ion mass spectrometry (SIMS); and

FIG. 23 is a graph showing results of measuring the number of oxygen (O) bonded with a metal element (Hf) and the ratio of the oxygen to the metal element (Hf) (O/Hf) for a metal oxide included in electro-chemical layers of memory devices according to examples and comparative examples of the present disclosure, using X-ray photoelectron spectroscopy (XPS).

### DETAILED DESCRIPTION

Prior to the detailed description of the present disclosure, it should be noted that terms or words used in the present specification and claims may not be construed as being limited to their usual or dictionary meanings. In addition, terms or words should be interpreted to have a meaning or concept that is consistent with the technical idea of the present disclosure based on the principle that the inventors are capable of appropriately defining the concept of the term to describe their disclosure. The example embodiments described in the present specification and configurations illustrated in the drawings are merely some example embodiments of the present disclosure and may not represent all of the technical ideas of the present disclosure. Accordingly, there may be various equivalents and variations capable of replacing the example embodiments or configurations at the time of filing of the present disclosure.

Like reference numerals or marks presented in each of drawings attached to the present specification may represent components or elements that perform substantially the same functions. For convenience of description and understanding, the same reference numbers or symbols may be used in different example embodiments. That is, even though components having the same reference number are depicted in a plurality of drawings, the plurality of drawings may not all represent one example embodiment.

When a component is described as being “on” or “in contact with” another component in the present specification, it is to be understood that the component may be directly on or connected to the other component, but that there may be another component present between the components.

When a component is described as being “above” another component in the present specification, it is meant that the component is present above the another component in a vertical direction, and it is to be understood that the components may be in direct contact or connected or that still another component is present between the components. Further, when a component is described as being “below” another component in the present specification, it is meant that the component is present below the another component in the vertical direction, and it is to be understood that the components may be in direct contact or connected or that still another component is present between the components.

When a component is described as being “directly on,” “adjacent to,” or “in contact with” another component in the present specification, it is to be understood that no other component is present between the components. Other similar expressions that describe positional relationships between components may be interpreted in the same way.

When a component is described in the present specification as being “disposed” on (on the surface of) another component, it is to be understood that the component is in contact with or spaced apart from the surface of the other component, but is present in a corresponding position.

In the following description, any references to the singular may include the plural unless expressly stated otherwise in the context. It is to be understood that the terms “includes” and/or “comprises”, when used in the present specification, specify the presence of stated features, numbers, steps, operations, elements, components, or combinations thereof, but do not preclude the presence or addition of one or more other features, numbers, steps, operations, elements, components, or combinations thereof.

In the description below, expressions such as an upper side, an upper surface, a lower side, a lower surface, a side surface, a front surface, a rear surface, or the like, are expressed based on a direction shown in the drawing, and may be differently expressed when the direction of a corresponding object changes.

Terms including ordinal numbers, such as “first,” “second,” etc., may be used in the present specification and claims to distinguish between components. The ordinals are sometimes used to distinguish between identical or similar components, and the use of the ordinals should not be interpreted in a limited way in the meaning of the terms. For example, components associated with the ordinals should not be construed as limiting the order of use or arrangement, etc., by their numbers. The ordinals may be interchangeably used as needed.

While the term “same,” “equal” or “identical” is used in the description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not desired but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of,” “any one of,” and “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

The properties described in the specification may be measured in a room temperature and natural pressure environment unless specifically limited. In the specification, as the natural temperature without any artificial manipulation, the room temperature may be 10° C. to 30° C., 20° C. to 28° C. or 22° C. to 26° C. In an example embodiment, the room temperature may be 25° C. In an example embodiment, as a natural pressure without any artificial manipulation, the pressure may be between 700 mmHg and 800 mmHg or between 720 mmHg and 780 mmHg, and in one example embodiment may be 760 mmHg.

Unless specifically limited in the present specification, units of physical properties may be applied in the SI unit system.

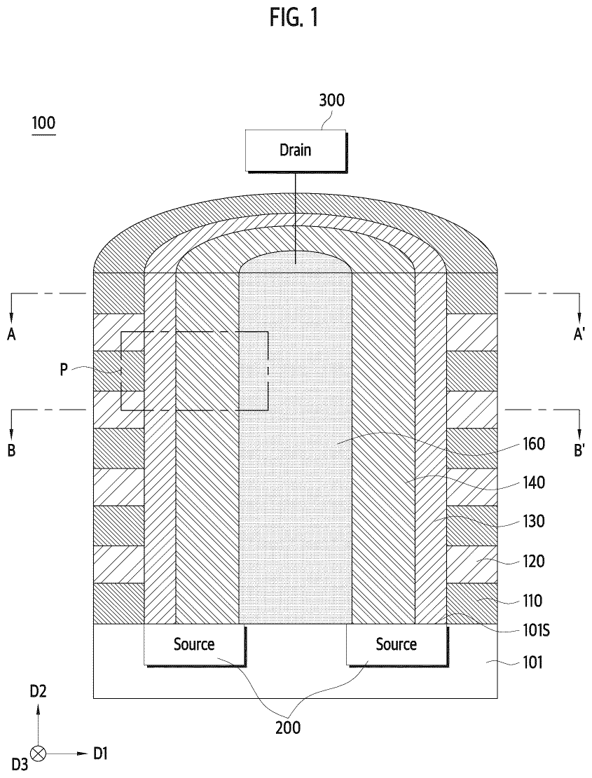

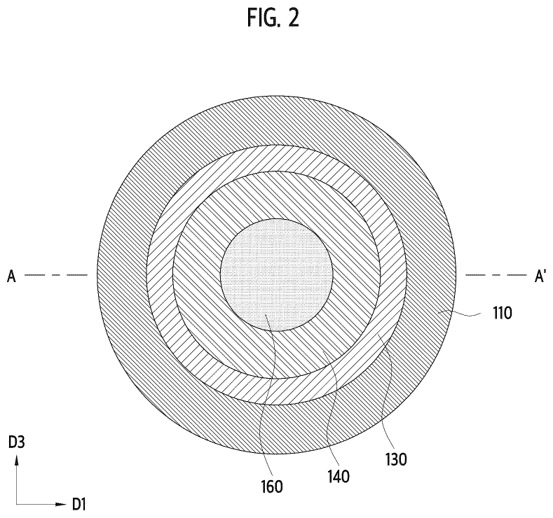

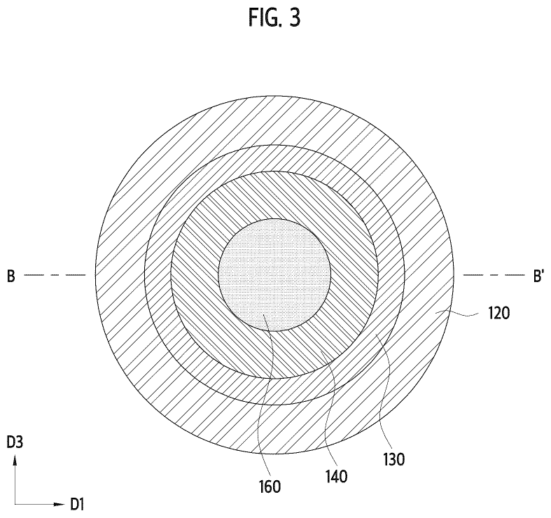

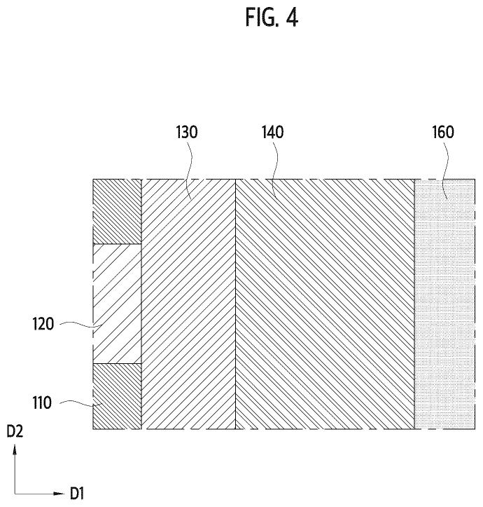

FIG. 1 schematically illustrates at least a portion of a memory device 100 according to an example embodiment of the present disclosure. FIG. 2 illustrates a cross-section taken along line AA′ of FIG. 1. FIG. 3 illustrates a cross-section taken along line BB′ of FIG. 1. FIG. 4 is an enlarged view of part P in FIG. 1.

The memory device 100 according to an example embodiment of the present disclosure may be, for example, a non-volatile memory device. In one example, the non-volatile memory device may be a flash memory, a read-only memory (ROM), a hard disk, a diskette drive, a magnetic tape, or an optical disc, but is not limited thereto. In one example, the non-volatile memory device may be a flash memory. In one example, the flash memory may be a NAND flash memory, and specifically may be a planar NAND flash memory or a vertical NAND flash memory. In one example, the memory device 100 may be a planar NAND flash memory device or a vertical NAND flash memory device.

The memory device 100 according to an example embodiment of the present disclosure may include a substrate 101, a gate electrode 120, a gate oxide layer 130, an electro-chemical layer 140, and a channel layer 160.

The substrate 101 according to an example embodiment of the present disclosure is not particularly limited, but may be a silicon semiconductor substrate, a plastic substrate, a glass substrate, a compound semiconductor substrate, a ceramic substrate, or a silicon-on-insulator (SOI) substrate. In one example, the substrate 101 may include, although not separately illustrated, an impurity region due to doping, a peripheral circuit for selecting and controlling an electronic element such as a transistor or a memory cell, or the like. In one example, the gate electrode 120, the gate oxide layer 130, the electro-chemical layer 140, and the channel layer 160 may be disposed on a surface 101S of the substrate.

In the present specification, a first direction D1 may be a direction parallel to the surface 101S of the substrate, as illustrated in FIG. 1. A second direction D2 may refer to a direction intersecting the first direction D1, and specifically, the second direction D2 may be a direction perpendicular to the surface 101S of the substrate while intersecting the first direction D1. A third direction D3 may be a direction intersecting the first direction D1 as illustrated in FIG. 1, but is parallel to the surface 101S of the substrate.

The gate electrode 120 according to an example embodiment of the present disclosure may be electrically connected to a word line. In one example, the gate electrode 120 may include a conductive material. In the present specification, the conductive material may include one or more selected from the group consisting of metal, metal nitride, metal silicide, and metal oxide. In the present specification, the metal may include one or more selected from the group consisting of gold (Au), silver (Ag), platinum (Pt), calcium (Ca), ytterbium (Yb), aluminum (Al), copper (Cu), titanium (Ti), tantalum (Ta), rubidium (Rb), tungsten (W), molybdenum (Mo), nickel (Ni), tin (Sn), palladium (Pd), lead (Pb), and cobalt (Co), but is not limited thereto. In the present specification, the metal nitride may include one or more selected from the group consisting of titanium nitride (TiN), titanium aluminum nitride (TiAlN), tantalum silicon nitride (TaSiN), and rubidium titanium nitride (RbTiN), but is not limited thereto. In the present specification, the metal silicide may include one or more selected from the group consisting of titanium silicide (TiSi), tantalum silicide (TaSi), nickel silicide (NiSi), and cobalt silicide (CoSi), but is not limited thereto. In the present specification, the metal oxide may include one or more selected from the group consisting of gold oxide (AuOx), platinum oxide (PtOₓ), silver oxide (AgOₓ), palladium oxide (PdOₓ), iridium oxide (IrOₓ), and rubidium oxide (RbOₓ), but is not limited thereto.

The gate electrode 120 according to an example embodiment of the present disclosure may be disposed on the channel layer 160.

Referring to FIG. 1, in one example, the gate electrode 120 may surround at least a portion of the channel layer 160. In one example, there may be a plurality of gate electrodes 120, and adjacent gate electrodes 120 may be spaced apart from each other based on the second direction D2.

The memory device 100 according to an example embodiment of the present disclosure may include an insulating layer 110.

Referring to FIG. 1, in one example, the insulating layer 110 may surround at least a portion of the channel layer 160. In one example, the insulating layer 110 may include an insulating material. In the present specification, the insulating material may include one or more selected from the group consisting of silicon oxide, silicon nitride, silicon oxynitride, low-k materials, and high-k materials, but is not limited thereto. In the present specification, the low-k material may have a permittivity less than 3.9, and may include, for example, one or more from the group consisting of fluorinated tetraethylorthosilicate (FTEOS), hydrogen silsesquioxane (HSQ), Bis-benzocyclobutene (BCB), tetramethylorthosilicate (TMOS), octamethylocyclotetrasiloxane (OMCTS), hexamethyldisiloxane (HMDS), trimethylsilyl borate (TMSB), diacetoxyditertiarybutosiloxane (DADBS), trimethylsilyl phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, and mesoporous silica, but is not limited thereto. In the present specification, the high-k material may have a permittivity of 3.9 or higher, and may include, for example, one or more from the group consisting of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate, but is not limited thereto.

There may be a plurality of insulating layers 110 according to the example embodiment of the present disclosure, and adjacent insulating layers 110 may be spaced apart from each other based on the second direction D2. In one example, the insulating layer 110 may be disposed so that a space between adjacent gate electrodes 120 is filled with the insulating layer. In one example, the insulating layer 110 may overlap the gate electrode 120 at least in a partial region when viewed in the second direction D2.

Referring to FIG. 1, in one example, the insulating layer 110 and the gate electrode 120 may have a structure in which they are alternately stacked, and the insulating layer 110 and the gate electrode 120 may be in contact with each other based on the second direction D2.

Referring to FIG. 2, the insulating layer 110 may surround at least a portion of the channel layer 160. Referring to FIG. 3, the gate electrode 120 may surround at least a portion of the channel layer 160.

The channel layer 160 according to an example embodiment of the present disclosure may be disposed on the surface 101S of the substrate.

Referring to FIG. 1, in one example, the channel layer 160 may extend along the second direction D2. In one example, the gate electrode 120 may surround at least a portion of the channel layer 160.

The channel layer 160 according to an example embodiment of the present disclosure may include a semiconductor oxide. In one example, the channel layer 160 may be a semiconductor oxide and include an oxide including one or more selected from the group consisting of tantalum (Ta), hafnium (Hf), aluminum (Al), zinc (Zn), tungsten (W), vanadium (V), titanium (Ti), neodymium (Nd), silicon (Si), germanium (Ge), arsenic (As), tellurium (Te), antimony (Sb), gallium (Ga), indium (In), zirconium (Zr), tin (Sn), and nickel (Ni). In one example, the channel layer 160 may include one or more selected from the group consisting of indium tungsten oxide (IWO), indium tin gallium oxide (ITGO), indium aluminum zinc oxide (IAGO), indium gallium oxide (IGO), indium tin zinc oxide (ITZO), zinc tin oxide (ZTO), indium zinc oxide (IZO), zinc oxide (ZnO), tungsten oxide (WO), indium oxide (InO), tin oxide (SnO), titanium oxide (TiO), magnesium zinc oxide (MgZnO), indium zinc oxide (InZnO), indium gallium zinc oxide (IGZO, InGaZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO), zirconium zinc tin oxide (ZrZnSnO), and indium gallium silicon oxide (InGaSiO), but is not limited thereto. In one example, in some cases, the channel layer 160 may include oxygen ions. The channel layer 160 may include oxygen ions by including a semiconductor oxide.

The electro-chemical layer 140 according to an example embodiment of the present disclosure may be disposed between the channel layer 160 and the gate electrode 120. In one example, the electro-chemical layer 140 may include oxygen ions. In one example, the electro-chemical layer 140 may receive oxygen ions from the channel layer 160 or transfer oxygen ions to the channel layer 160 depending on the voltage applied to the gate electrode 120. That is, the electro-chemical layer 140 may include oxygen ions to be transferred to the channel layer 160 or oxygen ions transferred from the channel layer 160 depending on the voltage applied to the gate electrode 120.

In the present specification, the movement of oxygen ions may be performed in the opposite direction to the movement of oxygen vacancies. In some example embodiments, the electro-chemical layer 140 may exchange oxygen ions with the channel layer 160, and change the electrical conductivity and a threshold voltage Vₜₕ of the channel layer 160 depending on the degree of exchange of oxygen ions. Hereinafter, movement of oxygen vacancy is mainly described, but as described above, the movement of oxygen vacancies may also be interpreted as movement of oxygen ions.

The electro-chemical layer 140 according to an example embodiment of the present disclosure may include oxygen ions. A concentration of oxygen ions in the electro-chemical layer 140 according to an example embodiment of the present disclosure may be, for example, less than 90%, 89.5% or less, 89% or less, 88.5% or less, 88% or less, 87.5% or less, 87% or less, 86.5% or less, 86% or less, 85.5% or less, or 85% or less.

For example, the concentration of oxygen ions in the electrochemical layer 140 according to an example embodiment of the present disclosure may be 50% or greater, 51% or greater, 52% or greater, 53% or greater, 54% or greater, 55% or greater, 56% or greater, 57% or greater, 58% or greater, 59% or greater, 60% or greater, 61% or greater, 62% or greater, 63% or greater, 64% or greater, 65% or greater, 66% or greater, 67% or greater, 68% or greater, or 69% or greater. However, the concentration of oxygen ions in the electrochemical layer 140 is not limited thereto. Here, the concentration of oxygen ions in the electrochemical layer 140 may be based on the time when the memory device 100 is in its initial state and has not performed a write operation, or when an erase operation is performed and the state is maintained even if the write operation is performed.

The electro-chemical layer 140 according to the example embodiment of the present disclosure may include metal oxide having a metal element (M)-oxygen (O) bond. In some example embodiments, the metal oxide included in the electro-chemical layer 140 may include one or more of a single metal oxide in which one metal element (M) and oxygen (O) are bonded or a composite metal oxide in which two or more metal elements (M) and oxygen (O) are bonded.

In one example, the metal element M may include one or more selected from the group consisting of transition metal elements TM of groups 3 to 6, but is not limited thereto. In one example, the transition metal element may include a group 3 transition metal element such as scandium (Sc), iridium (Ir), or lanthanum (La), but is not limited thereto. In one example, the transition metal element may include a group 4 transition metal element such as titanium (Ti), zirconium (Zr), hafnium (Hf), or rutherfordium (Rf), but is not limited thereto. In one example, the transition metal element may include a group 5 transition metal element such as vanadium (V) or tantalum (Ta), but is not limited thereto. In one example, the transition metal element may include a group 6 transition metal element such as chromium (Cr), molybdenum (Mo), or tungsten (W), but is not limited thereto. In one example, the metal element M may include a group 4 transition metal element TM, for example, the group 4 transition metal element TM may include hafnium (Hf).

In the present specification, the concentration of oxygen ions for the metal oxide may be calculated, for example, according to the following equation 1, but is not limited thereto.

$$Concentration of oxygen ions ( \% ) = \frac{{O}_{b}}{M \times {n}_{M}} \times 100 ( \% ) \qquad [ Equation 1 ]$$

In Equation 1, M represents the number of metal elements included in the metal oxide, nm represents a value obtained by dividing the valency of the metal element included in the metal oxide by 2, and O_{b} represents the number of oxygen atoms bonded with the metal element in the metal oxide. In Equation 1, M and O_{b} may represent the number for the all metal oxides in the electro-chemical layer 140.

In one example, the memory device 100 may satisfy one or more of a) to d) below.

In one example, a) metal element M is a group 3 transition metal element, and a ratio (O_{b3}/TM₃) of the number O_{b3} of oxygen atoms bonded to group 3 transition metal elements and the number TM₃ of group 3 transition metals may be less than 1.35.

In one example, b) metal element M is a group 4 transition metal element, and a ratio (O_{b4}/TM₄) of the number O_{b4} of oxygen atoms bonded to group 4 transition metal elements TM₄ and the number TM₄ of group 4 transition metals may be less than 1.8.

In one example, c) metal element M is a group 5 transition metal element, and a ratio (O_{b5}/TM₅) of the number O_{b5} of oxygen atoms bonded to group 5 transition metal elements and the number TM₅ of group 5 transition metals may be less than 2.25.

In one example, d) metal element M is a group 6 transition metal element, and a ratio (O_{b6}/TM₆) of the number O_{b6} of oxygen atoms bonded to group 6 transition metal elements and the number TM₆ of group 6 transition metals may be less than 2.7. In one example, the memory device may satisfy at least one of a) to d) described above.

In the memory device 100 according to an example embodiment of the present disclosure, a) metal element M is a group 3 transition metal element, and a ratio (O_{b3}/TM₃) of the number O_{b3} of oxygen atoms bonded to group 3 transition metal elements and the number TM₃ of group 3 transition metals may be 0.75 or more. In one example, in the memory device 100, b) metal element M is a group 4 transition metal element, and a ratio (O_{b4}/TM₄) of the number O_{b4} of oxygen atoms bonded to the group 4 transition metal elements TM₄ and the number TM₄ of group 4 transition metals may be 1.8 or more. In one example, in the memory device 100, c) metal element M is a group 5 transition metal element, and a ratio (O_{b5}/TM₅) of the number O_{b5} of oxygen atoms bonded to the group 5 transition metal elements and the number TM₅ of group 5 transition metals may be 1.25 or more. In one example, in the memory device 100, d) metal element M is a group 6 transition metal element, and a ratio (O_{b6}/TM₆) of the number O_{b6} of oxygen atoms bonded to the group 6 transition metal elements and the number TM₆ of group 6 transition metals may be 1.5 or more.

In one example, when a positive voltage is applied to the gate electrode 120, oxygen vacancies present in the electro-chemical layer 140 may be transferred to the channel layer 160. In one example, when a negative voltage is applied to the gate electrode 120, oxygen vacancies present in the channel layer 160 may be transferred to the electro-chemical layer 140. Through this process, the electro-chemical layer 140 may exchange oxygen vacancies with the channel layer 160, and change the electrical conductivity and the threshold voltage Vₜₕ of the channel layer 160 depending on the degree of exchange of oxygen vacancies. Meanwhile, as described above, the behavior of oxygen ions may be explained in the opposite way to that of oxygen vacancies.

The gate oxide layer 130 according to an example embodiment of the present disclosure may be disposed between the gate electrode 120 and the electro-chemical layer 140. In one example, the gate oxide layer 130 may include one or more selected from the group consisting of metal oxide, silicon oxide, silicon nitride, silicon oxynitride, a low-k material, and a high-k material, but is not limited thereto. In one example, the metal oxide may include one or more selected from the group consisting of, for example, aluminum oxide (AlO) and tin oxide (SnO).

The memory device 100 according to an example embodiment of the present disclosure may include a source electrode 200 and a drain electrode 300. In one example, the channel layer 160 may be connected to a source and a drain.

In one example, referring to FIG. 1, the source electrode 200 and a drain electrode 300 may be spaced apart from each other based on the second direction D2. In one example, the source electrode 200 and the drain electrode 300 may each independently include a conductive material.

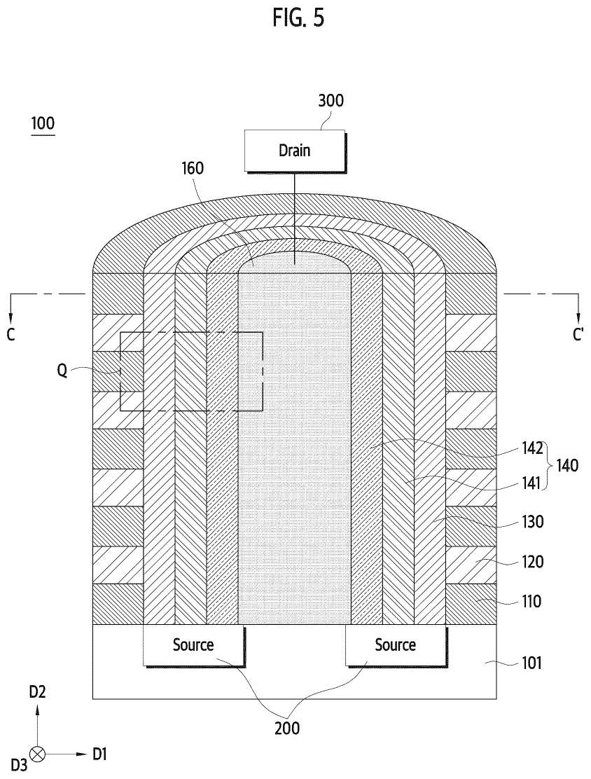

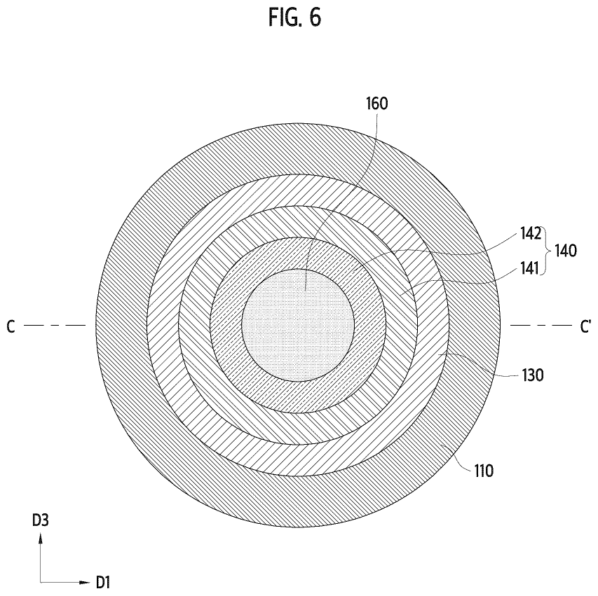

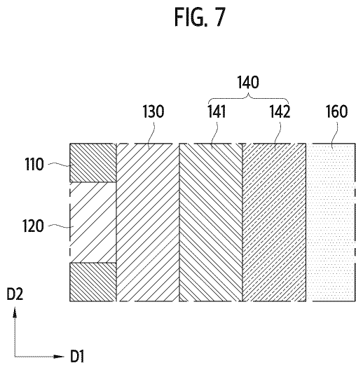

FIG. 5 schematically illustrates at least a portion of an electro-chemical memory device 100 according to an example embodiment of the present disclosure. FIG. 6 illustrates a cross-section taken along CC′ of FIG. 5. FIG. 7 is an enlarged view of part Q in FIG. 5.

The electro-chemical layer 140 according to the example embodiment of the present disclosure may include one or more of a reservoir layer 141 and an electrolyte layer 142. In one example, the electro-chemical layer 140 may include the reservoir layer 141 and the electrolyte layer 142 disposed to be further away from the gate electrode 120 than the reservoir layer 141. In one example, the contents of the reservoir layer 141 and the electrolyte layer 142 may refer to the description of the electro-chemical layer 140 unless contradictory.

For example, in some cases, the reservoir layer 141 may include oxygen ions. For example, the concentration of oxygen ions in the reservoir layer 141 may be less than 90%, 89.5% or less, 89% or less, 88.5% or less, 88% or less, 87.5% or less, 87% or less, 86.5% or less, 86% or less, 85.5% or less, or 85% or less, and may be 50% or greater, 51% or greater, 52% or greater, 53% or greater, 54% or greater, 55% or greater, 56% or greater, 57% or greater, 58% or greater, 59% or greater, 60% or greater, 61% or greater, 62% or greater, 63% or greater, 64% or greater, or 65% or greater. However, the concentration of oxygen ions in the reservoir layer 141 is not limited thereto.

In one example, when a positive voltage is applied to the gate electrode 120, oxygen vacancies present in the reservoir layer 141 may be transferred to the channel layer 160. In one example, when a negative voltage is applied to the gate electrode 120, oxygen vacancies present in the channel layer 160 may be transferred to the reservoir layer 141. Through the process, the reservoir layer 141 may exchange oxygen vacancies with the channel layer 160, thereby changing the electrical conductivity and/or the threshold voltage Vₜₕ of the channel layer 160 depending on the degree of exchange of oxygen vacancies.

In one example, the electrolyte layer 142 may pass oxygen vacancies therethrough such that oxygen vacancies are transferred from the channel layer 160 to the reservoir layer 141 or oxygen vacancies are smoothly transferred from the reservoir layer 141 to the channel layer 160 depending on the voltage applied to the gate electrode 120. That is, the electrolyte layer 142 may allow oxygen vacancies transferred from the reservoir layer 141 to the channel layer 160 or transferred from the channel layer 160 to the reservoir layer 141 depending on the voltage applied to the gate electrode 120 to pass therethrough. In one example, the electrolyte layer 142 may allow the channel layer 160 and the reservoir layer 141 to smoothly exchange oxygen vacancies with each other, thereby changing the electrical conductivity and/or the threshold voltage Vₜₕ of the channel layer 160 depending on the degree of exchange of oxygen vacancies.

The concentration of oxygen ions in the electrolyte layer 142 according to the embodiment of the present disclosure may be higher than the concentration of oxygen ions in the reservoir layer 141. Here, the concentration of oxygen ions in the electrolyte layer 142 and the concentration of oxygen ions in the reservoir layer 141 may be compared over time when the memory device 100 is in its initial state and has not performed a write operation, and when an erase operation is performed and the state is maintained even if the write operation is performed. Thereby, the oxygen vacancies of the reservoir layer 141 may be smoothly transferred through the electrolyte layer 142 to the channel layer 160.

The thickness of the electrolyte layer 142 according to an example embodiment of the present disclosure may be thinner than the thickness of the reservoir layer 141. Thereby, oxygen vacancies passing through the electrolyte layer 142 may more easily move to the reservoir layer 141 or the channel layer 160.

In one example, the reservoir layer 141 and the electrolyte layer 142 may each independently include metal oxide having the aforementioned metal element (M)-oxygen (O) bond. The metal oxide included in the reservoir layer 141 and the metal oxide included in the electrolyte layer 142 may be different from each other. For example, the metal element M included in the electrolyte layer 142 may include one or more selected from a group of metal elements consisting of cerium (Ce), gallium (Ga), nickel (Ni), aluminum (Al), zinc (Zn), arsenic (As), tellurium (Te), antimony (Sb), indium (In), and tin (Sn), in addition to the metals listed in the electro-chemical layer 140, but is not limited thereto. In one example, the metal oxide included in the electrolyte layer 142 may include one or more selected from the group consisting of hafnium oxide, cerium oxide, tantalum oxide, gallium oxide, nickel oxide, and aluminum oxide.

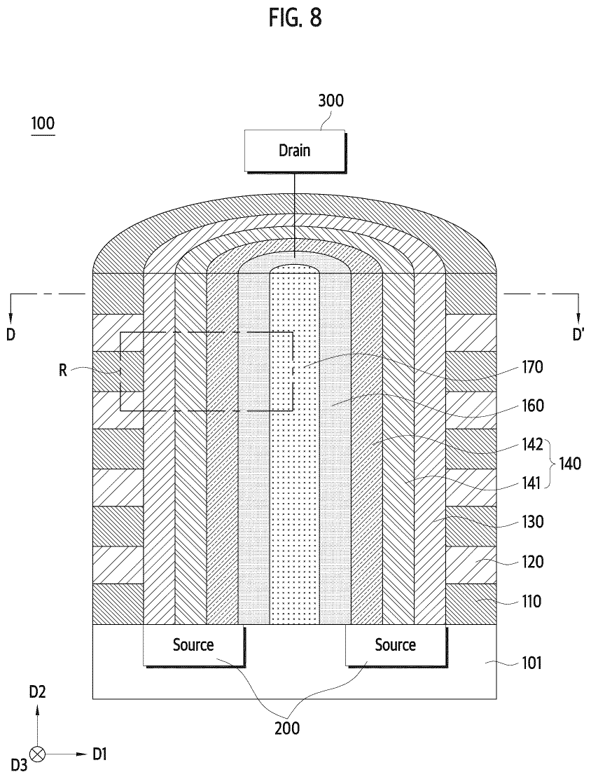

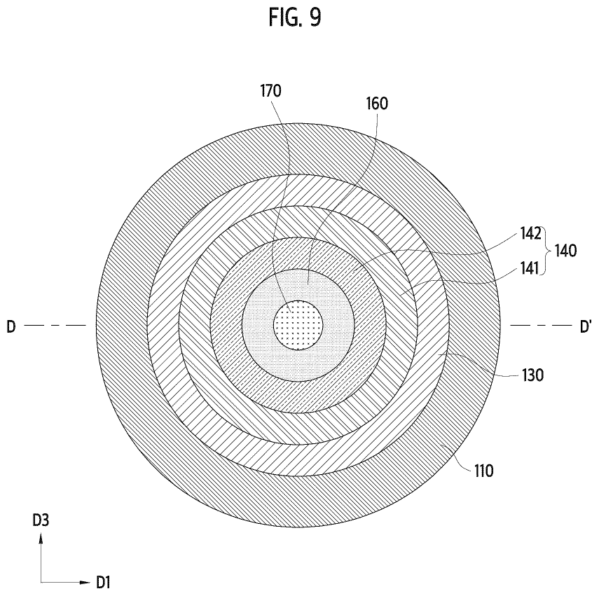

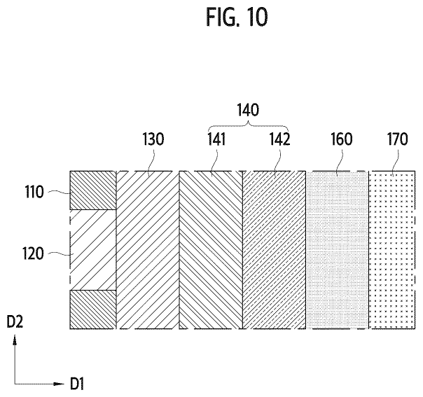

FIG. 8 schematically illustrates at least a portion of the memory device 100 according to an example embodiment of the present disclosure. FIG. 9 illustrates a cross-section taken along DD′ of FIG. 8. FIG. 10 is an enlarged view of part R in FIG. 8.

The memory device 100 according to an example embodiment of the present disclosure may include a filling layer 170 surrounded by the channel layer 160. In one example, the filling layer 170 may include an insulating material. In some cases, the filling layer 170 may include nitrogen (N₂), and in another example, the filling layer 170 may include nitrogen (N₂) and oxygen (O₂).

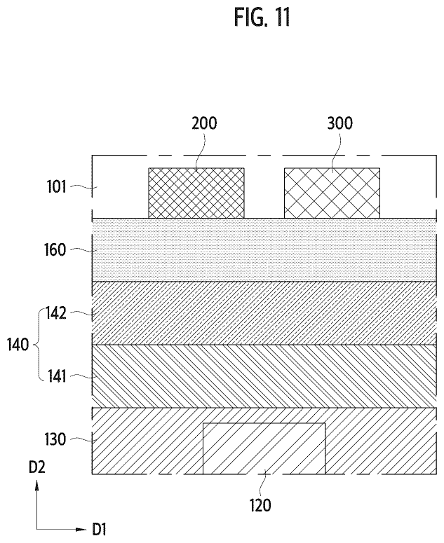

FIG. 11 schematically illustrates at least a portion of a memory device according to an example embodiment of the present disclosure. Unlike the memory devices 100 illustrated in FIGS. 1 to 10, the memory device 100 illustrated in FIG. 11 may have the channel layer 160 and the substrate 101 disposed parallel to each other. Hereinafter, the content of FIG. 11 may refer to the description of FIGS. 1 to 10 unless contradictory.

The gate electrode 120 according to an example embodiment of the present disclosure may be disposed between the substrate 101 and the channel layer 160 as described above.

Referring to FIG. 11, in one example, the gate electrode 120 may be disposed parallel to at least a portion of the channel layer 160. In one example, the channel layer 160 may be disposed parallel to the substrate 101. In one example, the channel layer 160 may be disposed parallel to the substrate 101 along the first direction D1.

Referring to FIG. 11, the memory device 100 according to an example embodiment of the present disclosure may include the source electrode 200 and a drain electrode 300. In one example, the source electrode 200 and the drain electrode 300 may be spaced apart from each other based on the first direction D1. For example, the source electrode 200 and the drain electrode 300 may be disposed on the channel layer 160 or inside the substrate 101.

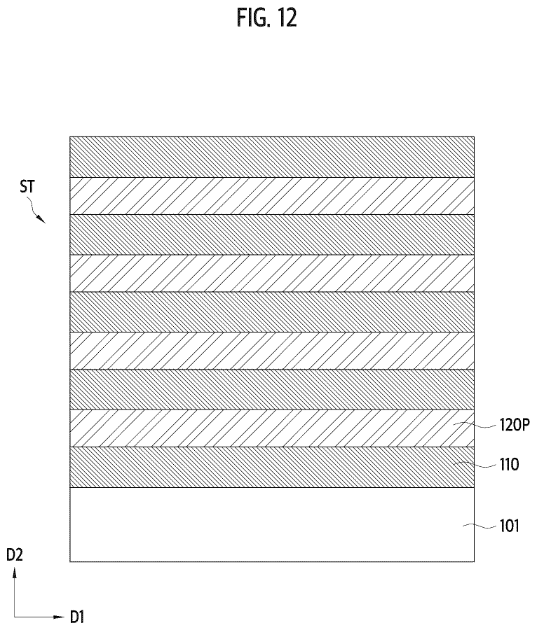

FIGS. 12 to 16 are views for describing a method of manufacturing the memory device 100 according to an example embodiment of the present disclosure. Hereinafter, the description of the method of manufacturing the memory device 100 may refer to the above-described contents described through FIGS. 1 to 11, unless contradictory. Hereinafter, the method of manufacturing the memory device 100 in which the channel layer 160 is formed by extending along a second direction D2 intersecting a first direction D1 parallel to the surface of the substrate 101 is described, but this is only for convenience of description and the method is not limited thereto.

Referring to FIG. 12, in one example, the method of manufacturing the memory device 100 may include forming a stack structure ST by alternating dielectric layers 120P and the insulating layers 110 on the substrate 101. The dielectric layer 120P may contain an insulating material. The dielectric layer 120P may contain a material different from the insulating layer 110. The dielectric layer 120P may include a material having a higher etching selectivity for a specific material compared to the insulating layer 110. For example, the insulating layer 110 may include an oxide (e.g., silicon oxide), and the dielectric layer 120P may include a nitride (e.g., silicon nitride). In one example, the dielectric layer 120P, which is closest to the substrate 101, may be positioned closer to the substrate 101 than the insulating layer 110, which is closest to the substrate 101.

In the specification, the specific film or layer is not particularly limited, but may be formed by, in one example, deposition. For example, the deposition may be performed by chemical vapor deposition (CVD), physical vapor deposition (PVD), or atomic layer deposition (ALD). If there is another method used in the art other than depositing a specific film or layer, for example, by coating, the method may be applied. Further, in the specification, certain films or layers are not specifically restricted, but may be removed by etching, in one example. Etching may be performed, for example, by dry etching or wet etching using phosphoric acid, and so on. The components of the memory device 100 may be formed, for example, through deposition, unless otherwise specified, but example embodiments are not limited thereto.

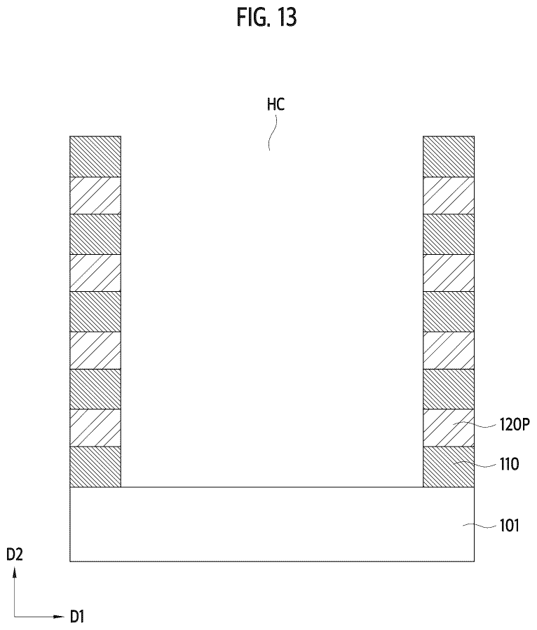

Referring to FIG. 13, in one example, the method of manufacturing the memory device 100 may include removing at least a portion of the stack structure ST to form an empty space HC. Forming an empty space HC in the stack structure ST may include forming a mask (not illustrated) other than the area where the empty space HC is to be formed, and removing the stack structure ST in the second direction D2 other than the area where the mask is formed through a photo process, etc. However, there are no particular limitations to the method as long as the empty space HC is formed in the stack structure ST. There may be one or two or more empty spaces HC, and in the case of two or more, each empty space HC may be formed to be spaced apart from each other.

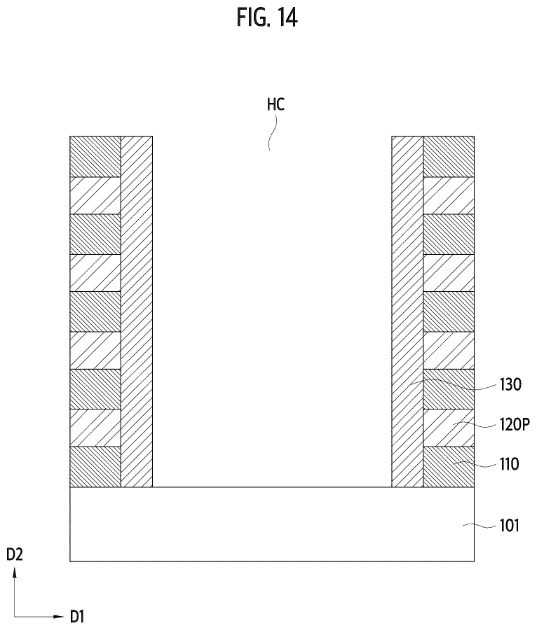

Referring to FIG. 14, in one example, the method of manufacturing the memory device 100 may include forming the oxide layer 130 on the substrate 101. A method of manufacturing the memory device 100 may include forming the oxide layer 130 within the empty space HC. At least a portion of the oxide layer 130 may be formed on the dielectric layer 120P. In other words, the method of manufacturing the memory device 100 may be formed so as to be placed on the gate electrode 120 described later. A portion of the oxide layer 130 may be formed on the dielectric layer 120P, and another portion may be formed on the insulating layer 110. At least a portion of the oxide layer 130 may be formed to extend along the second direction D2. At least a portion of the oxide layer 130 may be in contact with the dielectric layer 120P. At least a portion of the oxide layer 130 may be in contact with both the insulating layer 110 and the dielectric layer 120P.

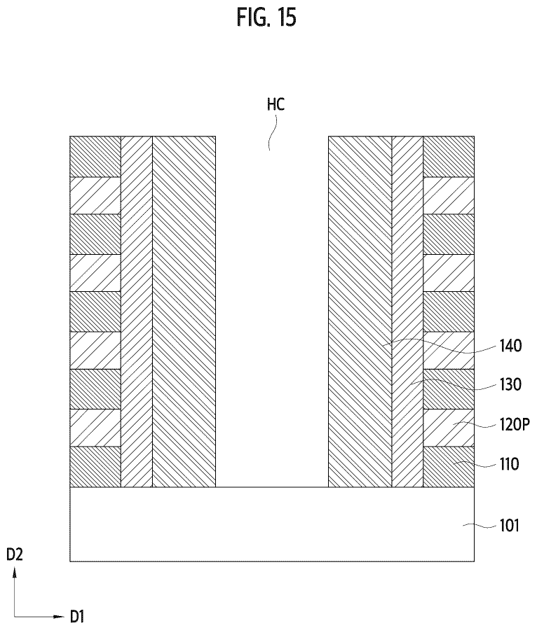

Referring to FIG. 15, in one example, the method of manufacturing the memory device 100 may include forming the electro-chemical layer 140 on the substrate 101. A method of manufacturing the memory device 100 may include forming the electro-chemical layer 140 within the empty space HC. In another example, a method for manufacturing the memory device 100 may include forming the electro-chemical layer 140 within the empty space HC while the oxide layer 130 is formed. At least a portion of the electro-chemical layer 140 may be formed on the oxide layer 130. At least a portion of the electro-chemical layer 140 may be formed to extend in the second direction D2.

For example, the electro-chemical layer 140 may be formed by deposition in an environment below 200° C., 190° C. or below, 180° C. or below, 170° C. or below, 160° C. or below, 150° C. or below, 140° C. or below, 130° C. or below, 120° C. or below, 110° C. or below, 100° C. or below, 90° C. or below, 80° C. or below, 70° C. or below, 60° C. or below, or 50° C. or below. Through this, the problem of oxygen vacancies being filled with impurities (e.g., carbon derived from metal precursors described later) may be reduced or minimized, and as described above, the electro-chemical layer 140 having an appropriate level of oxygen ion concentration may be manufactured. Through this, the memory window (M.W.) of the memory device 100 may be improved. The electro-chemical layer 140 may be formed by atomic layer deposition, although example embodiments are not limited to this method.

For example, the electro-chemical layer 140 may be deposited and formed in an environment of 1,000 mTorr or less, 900 mTorr or less, 800 mTorr or less, 700 mTorr or less, 600 mTorr or less, 500 m Torr or less, 400 mTorr or less, 300 mTorr or less, 200 mTorr or less, or 100 mTorr or less. Example embodiments of the present disclosure are not limited thereto. In some example embodiments, the electro-chemical layer 140 may be formed by deposition in an environment of 10 mTorr or greater, 20 mTorr or greater, 30 mTorr or greater, 40 mTorr or greater, 50 mTorr or greater, 60 mTorr or greater, 70 mTorr or greater, or 80 mTorr or greater. Through this, the problem of oxygen vacancies being filled with impurities (e.g., carbon derived from metal precursors described later) may be reduced or minimized, and as described above, the electro-chemical layer 140 having an appropriate level of oxygen ion concentration may be manufactured. Through this, the memory window (M.W.) of the memory device 100 may be improved.

The electro-chemical layer 140 may be formed via (e.g., based on) a metal precursor. For example, the metal precursor may have a thermal decomposition temperature of below 200° C., 190° C. or below, 180° C. or below, 170° C. or below, 160° C. or below, or 150° C. or below, but the thermal decomposition temperature of the metal precursor is not limited thereto. For example, the thermal decomposition temperature may be measured by thermogravimetric analysis (TGA). Through this, the electro-chemical layer 140 may be easily formed even at relatively low temperatures. The electro-chemical layer 140 formed in this way has a relatively low metal-to-oxygen ratio, and by reducing or minimizing the problem of filling the oxygen vacancy with impurities (e.g., carbon derived from a metal precursor described later), the memory window (M.W.) of the memory device 100 may be improved. The metal precursor is not particularly limited as long as it is used in the art, taking into account the type of metal element (M) to be included in the electro-chemical layer 140. For example, when the metal element (M) contains precursor may hafnium (Hf), the metal be tetrakis(ethylmethylamido) hafnium (TEMAHf).

If desired, the electro-chemical layer 140 may be formed via (e.g., based on) a metal precursor and a reactant gas. In this case, for example, the electro-chemical layer 140 may be formed by deposition in an environment of 150° C. or below, 140° C. or below, 130° C. or below, 120° C. or below, 110° C. or below, 100° C. or below, 90° C. or below, 80° C. or below, 70° C. or below, 60° C. or below, or 50° C. or below. The reactant gas may be an oxidizer. The reaction gas may be a gas at the thermal decomposition temperature of the metal precursor and at ambient pressure. The reactant gas may be liquid at room temperature and pressure. For example, the reactant gas may be water vapor (H₂O), but is not limited thereto. In some example embodiments, the electro-chemical layer 140 may be manufactured at relatively low temperatures by simultaneously reacting metal precursors and reactant gases.

Even though not illustrated in the drawings, in one example, a method of manufacturing the memory device 100 may include forming the reservoir layer 141 on the substrate 101. The method of manufacturing the memory device 100 may include forming the reservoir layer 141 within the empty space HC (see FIG. 5). In another example, the method for manufacturing the memory device 100 may include forming the reservoir layer 141 within the empty space HC while the oxide layer 130 is formed. At least a portion of the reservoir layer 141 may be formed on the oxide layer 130. The manufacturing process of the reservoir layer 141 may be referred to the manufacturing process of the electro-chemical layer 140 described above. At least a portion of the reservoir layer 141 may be in contact with the oxide layer 130. At least a portion of the reservoir layer 141 may be formed to extend in the second direction D2.

Even though not illustrated in drawings, in one example, a method of manufacturing the memory device 100 may include forming the electrolyte layer 142 on the substrate 101. The method of manufacturing the memory device 100 may include forming the electrolyte layer 142 within the empty space HC (see FIG. 5). In another example, the method for manufacturing the memory device 100 may include forming the electrolyte layer 142 within the empty space HC while the reservoir layer 141 is formed. At least a portion of the electrolyte layer 142 may be formed on the reservoir layer 141. The process of manufacturing the electro-chemical layer 140 described above may be referred to for the process of manufacturing the electrolyte layer 142. At least a portion of the electrolyte layer 142 may be in contact with the reservoir layer 141. At least a portion of the electrolyte layer 142 may be formed to extend in the second direction D2.

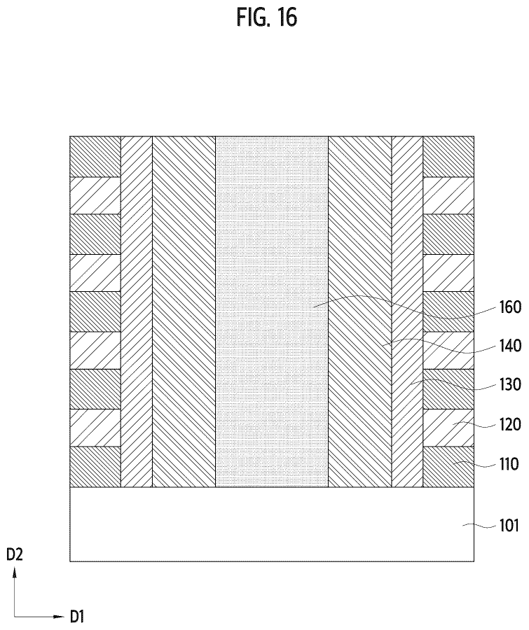

Referring to FIG. 16, in one example, the method of manufacturing the memory device 100 may include forming the channel layer 160 on the substrate 101. The method of manufacturing the memory device 100 may include forming the channel layer 160 within the empty space HC. In another example, a method for manufacturing the memory device 100 may include forming the channel layer 160 within the empty space HC while the electro-chemical layer 140 is formed. In another example, a method for manufacturing the memory device 100 may include forming the channel layer 160 within the empty space HC while the electrolyte layer 142 is formed. At least a portion of the channel layer 160 may be formed on the electro-chemical layer 140. In another example, at least a portion of the channel layer 160 may be formed on the electrolyte layer 142. At least a portion of the channel layer 160 may be formed to extend in the second direction D2. At least a portion of the channel layer 160 may be in contact with the electro-chemical layer 140. In another example, at least a portion of the channel layer 160 may be in contact with the electrolyte layer 142.

In one example, a method of manufacturing the memory device 100 may include forming the gate electrode 120. The method of manufacturing the memory device 100 may include forming the gate electrode 120 using the dielectric layer 120P. The gate electrode 120 may be formed through a replacement process known in the art. The dielectric layer 120P may be a so-called sacrificial layer, and the gate electrode 120 may be formed by replacing the sacrificial layer and a conductive material filling the space of the sacrificial dielectric layer 120P.

Even though not illustrated in the drawings, in one example, a method of manufacturing the memory device 100 may include forming the filling layer 170. The method of manufacturing the memory device 100 may include forming the filling layer 170 within the empty space HC (see FIG. 8). In another example, a method of manufacturing the memory device 100 may include filling the filling layer 170 within the empty space HC while the channel layer 160 is formed.

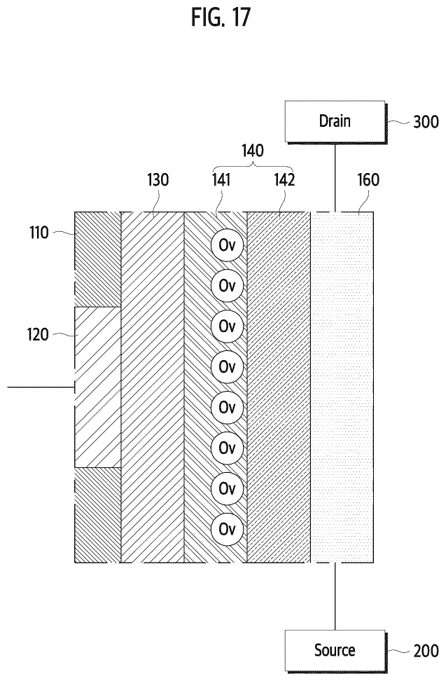

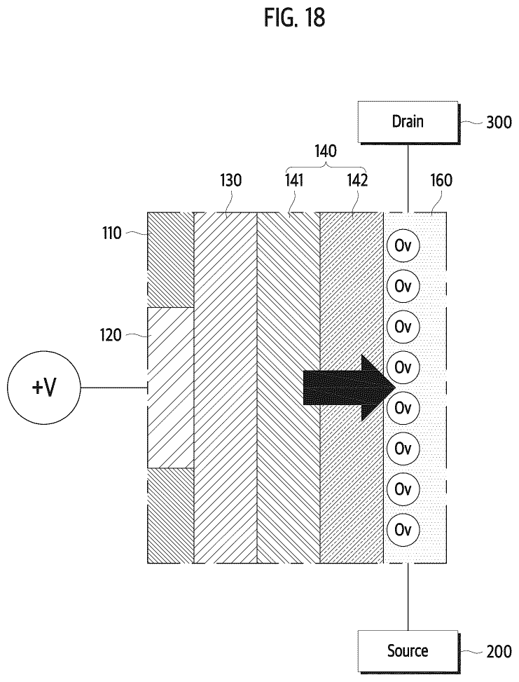

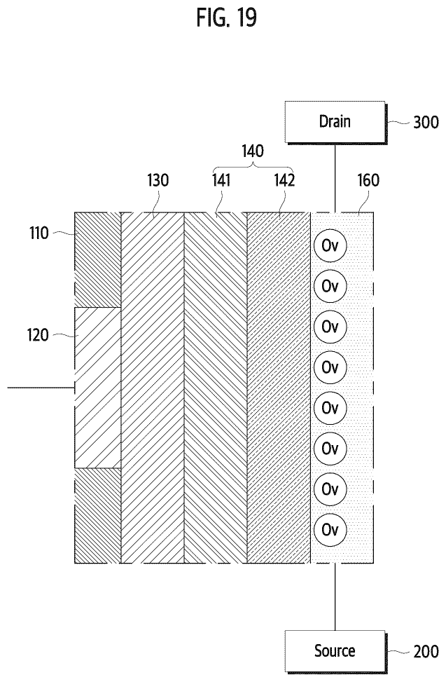

FIGS. 17 to 20 schematically illustrate at least a portion of the memory device 100 to describe a method of driving the memory device 100 according to an example embodiment of the present disclosure.

In the method of driving the memory device 100 according to an example embodiment of the present disclosure, when a voltage is applied to the gate electrode 120, the channel layer 160 and the electro-chemical layer 140 may exchange oxygen vacancies Ov with each other. In one example, when a voltage is applied to the gate electrode 120, oxygen vacancies Ov present in the electro-chemical layer 140 may be transferred to the channel layer 160. Alternatively, when the voltage is applied to the gate electrode 120, the oxygen vacancies Ov present in the channel layer 160 may be transferred to the electro-chemical layer 140. Thereby, the electrical conductivity and/or the threshold voltage Vₜₕ of the channel layer 160 may be changed from the electrical conductivity and/or the threshold voltage Vₜₕ of the channel layer 160 before the voltage is applied to the gate electrode 120, respectively.

In one example, when the electro-chemical layer 140 includes the reservoir layer 141 and the electrolyte layer 142, the reservoir layer 141 may be operated in the same manner as the driving principle of the electro-chemical layer 140 described above when a voltage is applied to the gate electrode 120. The electrolyte layer 142 may allow oxygen vacancies Ov to pass therethrough to smoothly transfer the oxygen vacancies Ov from the channel layer 160 to the reservoir layer 141 or to smoothly transfer the oxygen vacancies Ov from the reservoir layer 141 to the channel layer 160.

In one example, when a voltage is applied to the gate electrode 120, the gate oxide layer 130 may allow the electro-chemical layer 140 to smoothly exchange the oxygen vacancies Ov with the channel layer 160, and block or prevent the oxygen vacancies Ov present in the electro-chemical layer 140 from being transferred to the gate electrode 120.

In one example, the method of driving the memory device 100 may include transferring the oxygen vacancies Ov present in the electro-chemical layer 140 to the channel layer 160 or transferring the oxygen vacancies Ov present in the channel layer 160 to the electro-chemical layer 140, when a voltage is applied to the gate electrode 120. In this case, the electrical conductivity and/or the threshold voltage Vₜₕ of the channel layer 160 may be changed from those before the voltage is applied to the gate electrode 120, respectively, and as the electrical conductivity and/or the threshold voltage Vₜₕ of the channel layer 160 are different, the method of driving the memory device 100 may include performing a write (or program) or erase operation.

In one example, the method of driving the memory device 100 may include transferring, by the electro-chemical layer 140, oxygen vacancies Ov to the channel layer 160 and performing, by the channel layer 160, the write operation by which the electrical conductivity is increased, when a positive voltage is applied to the gate electrode 120. Here, the method of driving the memory device 100 may include performing an erase operation in which the electrical conductivity of the channel layer 160 returns close to the previous electrical conductivity by the channel layer 160 transferring the oxygen vacancies Ov to the electro-chemical layer 140 (e.g., the oxygen vacancies Ov present in the channel layer 160 going back to the electro-chemical layer 140), when the voltage is applied from the positive voltage to the negative voltage to the gate electrode 120.

In one example, the method of driving the memory device 100 may include transferring, by the channel layer 160, the oxygen vacancies Ov to the electro-chemical layer 140 and performing, by the channel layer 160, the write operation by which the electrical conductivity is decreased, when a negative voltage is applied to the gate electrode 120. Here, the method of driving the memory device 100 may include performing an erase operation in which the electrical conductivity of the channel layer 160 returns close to the previous electrical conductivity by the electro-chemical layer 140 transferring the oxygen vacancies Ov to the channel layer 160 (e.g., the oxygen vacancies Ov present in the electro-chemical layer 140 going back to the channel layer 160), when the voltage is applied from the negative voltage to the positive voltage to the gate electrode 120.

In one example, the method of driving the memory device 100 may include performing the write or erase operation as the threshold voltage Vₜₕ changes when the voltage is applied to the gate electrode 120. In one example, the threshold voltage Vₜₕ of the channel layer 160 may be changed as the electrical conductivity of the channel layer 160 changes. For example, when a positive voltage is applied to the gate electrode 120, the threshold voltage Vₜₕ may decrease.

In one example, the method of driving the memory device 100 may include performing a read operation to check a degree of inclusion of oxygen vacancies Ov (that is, the state of data) through the electrical conductivity of the channel layer 160 by applying a voltage to the gate electrode 120. As described above, since movement of oxygen vacancy Ov may be explained by the movement of oxygen ions, the degree of inclusion of oxygen ions may also be determined through the degree of inclusion of oxygen vacancy Ov. Here, it may be desirable that the voltage applied to the gate electrode 120 is low enough so that movement of the oxygen vacancies Ov does not occur. In addition, in one example, the degree of inclusion of the oxygen vacancies Ov present in the channel layer 160 may be measured as resistance through a current-voltage curve as well as the electrical conductivity of the channel layer 160, through which the read operation may be performed.

Hereinafter, some example embodiments of the present application are further described with reference to specific examples. The examples and comparative examples are intended to illustrate some examples of the present application only and not to limit the scope of the appended claims. It will be apparent to those skilled in the art that various changes and modifications to the these examples are possible within the scope and technical concepts of the present application. Such variations and modifications should be included in the scope of the appended claims.

### Example 1

The memory device 100 having a structure as in FIG. 5 was manufactured, which includes the channel layer 160 including indium gallium zinc oxide (IGZO), the reservoir layer 141 of the electro-chemical layer 140 including hafnium oxide, and the gate oxide layer 130 including aluminum oxide (AlO), where the thickness of the electro-chemical layer 140 including the reservoir layer 141 is about 8 nm and the thickness of the gate oxide layer 130 is about 10 nm. The electro-chemical layer 140 and the gate oxide layer 130 were formed using the atomic layer deposition (ALD) method. In this case, when the electro-chemical layer 140 is formed, atomic layer deposition was performed at about 50° C. and about 80 mTorr, tetrakis(ethylmethylamido) hafnium (TEMAHf) was used as a metal precursor, and water vapor (H₂O) was used as a reaction gas.

### Example 2

A memory device was manufactured in the same manner as in Example 1 described above, except that atomic layer deposition was performed at about 100° C. when forming the electro-chemical layer 140.

### Comparative Example 1

A memory device was manufactured in the same manner as in Example 1 described above, except that atomic layer deposition was performed at about 200° C. when forming the electro-chemical layer 140.

### Comparative Example 2

A memory device was manufactured in the same manner as in Example 1 described above, except that atomic layer deposition was performed at about 300° C. when forming the electro-chemical layer 140, Tris(dimethylamido)cyclopentadienyl Hafnium (ACP3) was used as a metal precursor, and ozone (O₃) was used as a reaction gas.

### Evaluation 1—Memory Window (M.W.) Measurement

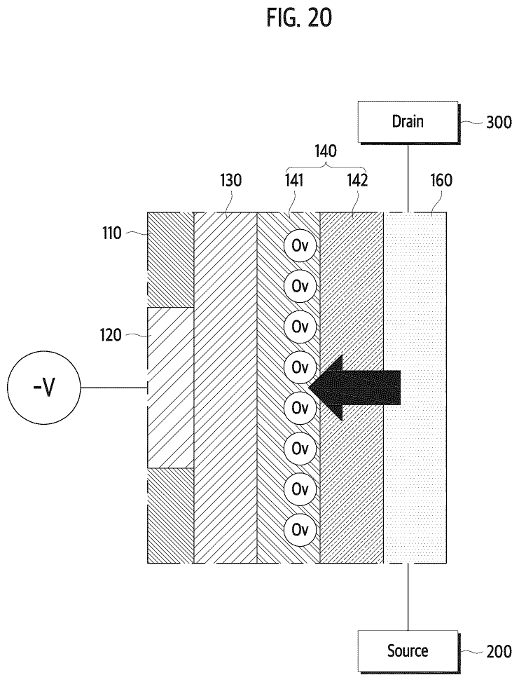

The characteristics of a drain-source current Ips with respect to a gate-source voltage V_{gs} (−12 V to +12 V) of the memory devices 100 of Example 1, Example 2, and Comparative Example 1 were measured. After performing one voltage sweep from −12 V→+12 V→−12 V, a graph was created and shown in FIG. 20 and Table 1.

TABLE 1

| | | | Comparative |
|---|---|---|---|
| Classification | Example 1 | Example 2 | Example 1 |
| Deposition | About 50 | About 100 | About 200 |
| temperature (° C.) | | | |
| Memory Window (V) | Up to about 11 | Up to about 7 | Up to about 4 |

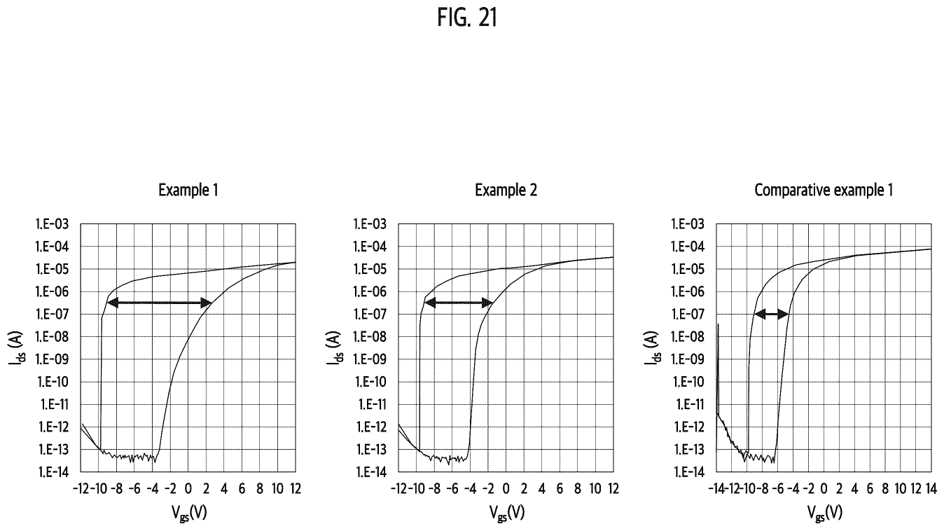

Referring to FIG. 21 and Table 1, it may be identified that the difference in I_{ds} for V_{gs} when the voltage increases and when the voltage decreases (e.g., the memory window) is relatively large in Example 1 and Example 2 compared to Comparative Example 1.

### Evaluation 2—Measurement of Impurity (Carbon) Content and Oxygen Ion Concentration

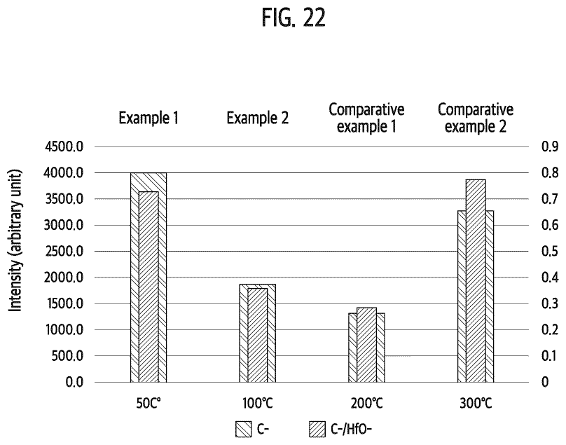

FIG. 22 shows the results of analyzing the carbon content (C) and the carbon content relative to hafnium (C/Hf) in the memory devices 100 of Example 1, Example 2, Comparative Example 1, and Comparative Example 2, using a secondary ion mass spectrometer (SIMS). Carbon is an impurity derived from the precursor used in the deposition process. Here, the content means atomic %.

Referring to FIG. 22, it may be identified that the impurity contents of Example 1 and Example 2 are at similar levels to the impurity contents of Comparative Example 2 and Comparative Example 1, respectively. By maintaining the impurity content below a certain range, the disadvantages in device behavior caused by impurities filling the spaces where oxygen vacancies may exist can be reduced, thereby reducing the deterioration of endurance and/or retention caused by carbon impurities.

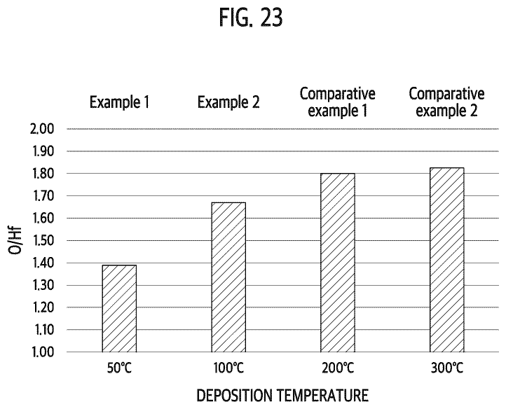

Meanwhile, results of calculating an O/Hf ratio, which is a ratio of the number of oxygen atoms bonded to a hafnium atom to the number of hafnium atoms, by analyzing the memory devices 100 of Example 1, Example 2, Comparative Example 1, and Comparative Example 2 using X-ray photoelectron spectroscopy (XPS) are shown in FIG. 23 and Table 2.

TABLE 2

| | | | Comparative | Comparative |
|---|---|---|---|---|
| Classification | Example 1 | Example 2 | Example 1 | Example 2 |
| O/Hf | 1.39 | 1.67 | 1.80 | 1.83 |
| Oxygen ion | 69.3 | 83.5 | 90.1 | 91.3 |
| concentration (%) | | | | |

Referring to FIG. 23 and Table 2, it may be identified that Example 1 and Example 2 have lower O/Hf values than Comparative Example 1 and Comparative Example 2.

In summary, it may be identified that Example 1 and Example 2 have a lower ratio of oxygen to metal, a lower oxygen ion concentration, and a higher memory window than Comparative Example 1 and Comparative Example 2, even though they have similar levels of impurity contents.

Some example embodiments of the present disclosure may provide memory devices capable of implementing a memory function even when a relatively small voltage is applied to a gate electrode while improving integration density and/or a driving method of the memory device, a method of manufacturing the memory devices, and a method of driving the memory devices. In addition, some example embodiments of the present disclosure may provide a memory device with an improved memory window (M.W.) by increasing the movement of oxygen ions in the operating principle of an electro-chemical random-access memory device, a method of manufacturing the memory device, and a method of driving the memory device.

Effects of the present disclosure are not limited to those mentioned above, and other effects not mentioned will be clearly understood by those skilled in the art from the description below.

The present disclosure is not limited to the above example embodiments and may be manufactured in various different forms, and those of ordinary skill in the art to which the present disclosure pertains may understand that the additional or alternative example embodiments may be embodied in other specific forms without departing from the technical spirit or essential features of the present disclosure. Therefore, it is to be appreciated that the example embodiments described above are intended to be illustrative in all respects and not restrictive.

What is claimed is:

1. A memory device comprising:
a substrate;
a channel layer on a surface of the substrate, the channel layer including an oxygen ion;
a gate electrode on the channel layer;
an electro-chemical layer between the channel layer and the gate electrode; and
a gate oxide layer between the gate electrode and the electro-chemical layer,
wherein the electro-chemical layer has a concentration of oxygen ions less than 90% and is capable of transferring the oxygen ions to the channel layer or receiving the oxygen ions from the channel layer, depending on a voltage applied to the gate electrode.

2. The memory device of claim 1, wherein
a first direction refers to a direction parallel to the surface of the substrate,
the channel layer extends along a second direction intersecting the first direction,
the gate electrode surrounds at least a first portion of the channel layer.

3. The memory device of claim 2, further comprising:
a source electrode and a drain electrode electrically connected to the channel layer,
wherein the source electrode and the drain electrode are spaced apart from each other based on the second direction.

4. The memory device of claim 2, further comprising:
an insulating layer overlapping the gate electrode in at least a partial region when viewed in the second direction, the insulating layer surrounding at least a second portion of the channel layer.

5. The memory device of claim 4, comprising:
a plurality of gate electrodes including the gate electrode,
wherein an adjacent pair of the plurality of gate electrodes are spaced apart from each other in the second direction, and
the insulating layer fills a space between the adjacent pair of the plurality of gate electrodes.

6. The memory device of claim 1, wherein the channel layer is parallel to the substrate.

7. The memory device of claim 6, further comprising:
a source electrode and a drain electrode electrically connected to the channel layer,
wherein the source electrode and the drain electrode are spaced apart from each other in a first direction parallel to the surface of the substrate.

8. The memory device of claim 1, wherein
the concentration of the oxygen ions included in the electro-chemical layer is 50% or greater.

9. The memory device of claim 1, wherein
the electro-chemical layer includes a reservoir layer and an electrolyte layer, the reservoir layer being adjacent to the gate electrode and including the oxygen ions, the electrolyte layer being adjacent to the channel layer.

10. The memory device of claim 9, wherein
the concentration of the oxygen ions included in the reservoir layer is less than 90%.

11. The memory device of claim 9, wherein
the reservoir layer and the electrolyte layer are in contact with each other at least in some region.

12. The memory device of claim 9, wherein
a first thickness of the electrolyte layer is thinner than a second thickness of the reservoir layer.

13. The memory device of claim 1, wherein
the electro-chemical layer includes metal oxide having a bond of a metal element (M) and oxygen (O).

14. The memory device of claim 13, wherein
the metal element (M) includes one or more selected from group consisting of a group 3 transition metal elements (TM), group 4 transition metal elements, group 5 transition metal elements, and group 6 transition metal elements.

15. The memory device of claim 14, wherein at least one of conditions a) to d) is satisfied:
a) the metal element (M) is a group 3 transition metal element, and a first ratio (O_{b3}/TM₃) of a first number (O_{b3}) of oxygen atoms bonded to the group 3 transition metal elements and a second number (TM₃) of the group 3 transition metal elements is less than 1.35;
b) the metal element (M) is a group 4 transition metal element, and a second ratio (O_{b4}/TM₄) of a third number (O_{b4}) of the oxygen atoms bonded to the group 4 transition metal elements (TM₄) and a fourth number (TM₄) of the group 4 transition metal elements is less than 1.8;
c) the metal element (M) is a group 5 transition metal element, and a third ratio (O_{b5}/TM₅) of a fifth number (O_{b5}) of the oxygen atoms bonded to the group 5 transition metal elements and a sixth number (TM₅) of the group 5 transition metal elements is less than 2.25; and
d) the metal element (M) is a group 6 transition metal element, and a fourth ratio (O_{b6}/TM₆) of a seventh number (O_{b6}) of the oxygen atoms bonded to the group 6 transition metal elements and an eighth number (TM₆) of the group 6 transition metal elements is less than 2.7.

16. The memory device of claim 1, further comprising:
a filling layer surrounded by the channel layer,
wherein the filling layer includes an insulating material.

17. A method of driving a memory device, wherein
the memory device comprising
a substrate,
a channel layer on a surface of the substrate and comprising an oxygen ion,
a gate electrode between the substrate and the channel layer,
an electro-chemical layer between the channel layer and the gate electrode and comprising oxygen ions, and
a gate oxide layer between the gate electrode and the electro-chemical layer, and
performing a write operation or an erase operation when a voltage is applied to the gate electrode by changing first values of an electrical conductivity and a threshold voltage Vₜₕ of the channel layer differently from second values before the voltage is applied to the gate electrode, and
a concentration of the oxygen ions included in the electro-chemical layer is less than 90%.

18. The method of claim 17, wherein
the write operation comprises applying a positive voltage to the gate electrode in order for the electrical conductivity of the channel layer to increase or the threshold voltage Vₜₕ to decrease compared to the electrical conductivity and the threshold voltage Vₜₕ before the positive voltage is applied to the gate electrode, or
the erase operation comprises applying a negative voltage to the gate electrode in order for the electrical conductivity of the channel layer to return close to the electrical conductivity before the positive voltage is applied to the gate electrode.

19. A method of manufacturing a memory device, the method comprising
forming an oxide layer, an electro-chemical layer and a channel layer on a substrate,
wherein the electro-chemical layer is deposited in an environment below 200° C. based on a metal precursor, and
wherein a thermal decomposition temperature of the metal precursor is below 200° C.

20. The method of claim 19, wherein the electro-chemical layer is deposited based on the metal precursor and a reactant gas.
